(19) United States
(12) Patent Application Publication
(10) Pub. No.: US 2009/0288860 A1
(43) Pub. Date: Nov. 26, 2009

(54) FLEXIBLE PRINTED CIRCUIT AND METHOD FOR MAKING SAME

(75) Inventor: HUNG-TA LIN, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: CHI MEI COMMUNICATION SYSTEMS, INC., Tu-Cheng City (TW)

(21) Appl. No.: 12/199,896

(22) Filed: Aug. 28, 2008

(30) Foreign Application Priority Data
May 23, 2008 (CN) 200810301763.4

(51) Int. Cl. H05K 1/02; H05K 3/00

(52) U.S. Cl. 174/254; 29/831

(57) ABSTRACT

A flexible printed circuit (100) includes a main body (10) and at least one grounding layer (30). The main body includes a first connecting end (11), a band portion (12) and a second connecting end (13). The first connecting end and the second connecting end dispose a first connector (112) and a second connector (132) electrically connected with the first connecting end and the second connecting end, respectively. The band portion has a plurality of circuits, including grounding circuits, to electrically connect with the first connector and the second connector. The band portion defines a plurality of via holes (121). The grounding layer is disposed on a surface of the main body, and electrically connects with the grounding circuits of the band portion by via holes. The invention also provides a method for making the flexible printed circuit.

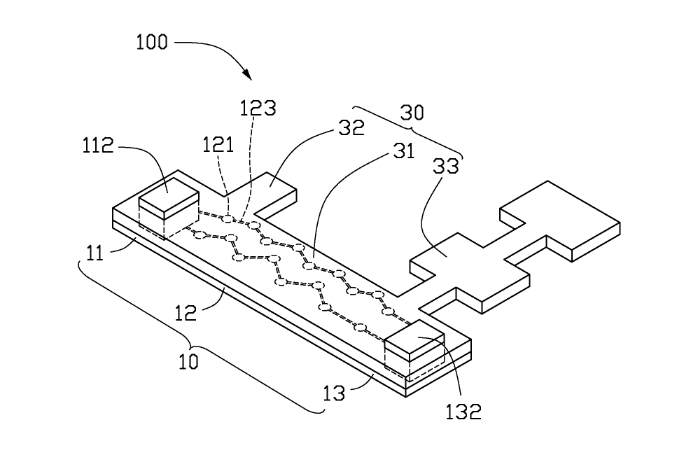

### BACKGROUND OF THE INVENTION

1. Technical field

The present invention generally relates to a flexible printed circuit, particularly to a flexible printed circuit configured for increased grounding contact and the method for making the flexible printed circuit.

2. Discussion of the Related Art

The flexible printed circuit (FPC) is widespread used within electronic devices such as mobile phones and personal digital assistants (PDAs) because of their light weight, thin thickness and are easy to bend for assembling.

With miniaturization of electronic devices, space within the electronic device for receiving electronic components is reduced. When the electronic device is in use, electronic components and circuits assembled within the electronic device might generate electrostatic charges. If the electrostatic charges generated within the electronic device cannot be effectively released to ground, electrostatic discharge (ESD) might occur among the electronic components and circuits and thus damage the electronic device. To avoid the above-described damage to the electronic device, a grounding device is provided and electrically connected to the electronic components and the circuits to the grounding device by the FPC to timely release the electrostatic charges of the electronic components and the circuits to ground by the grounding device.

However, due to limits to the dimensions of the connector of the FPC, the FPC sometimes cannot provide enough grounding pins. Therefore, the FPC cannot provide enough grounding contacts to release the electrostatic charges.

Therefore, there is room for improvement within the art.

### BRIEF DESCRIPTION OF THE DRAWING

Many aspects of the present flexible printed circuit and method for making the flexible printed circuit can be better understood with reference to the following drawings. The components in the drawings are not necessarily drawn to scale, the emphasis instead being placed upon clearly illustrating the principles of the present flexible printed circuit and method for making the flexible printed circuit.

The drawing shows a schematic, perspective view of a flexible printed circuit, in accordance with an exemplary embodiment of the present invention.

### DETAILED DESCRIPTION OF THE EMBODIMENT

The drawing shows a schematic, perspective view of a flexible printed circuit 100, according to an exemplary embodiment of the invention. The flexible printed circuit 100 includes a main body 10 and at least one ground layer 30. The main body 10 comprises a conventional flexible printed circuit board, including a first connecting end 11, a band portion 12 and a second connecting end 13. The first connecting end 11 and the second connecting end 13 are electrically connected to a first connector 112 and a second connector 132, respectively. The band portion 12 defines a plurality of via holes 121 and has a plurality of circuits 123, including grounding circuits, that electrically connect with the first connector 112 and the second connector 132.

The ground layer 30 is made of an electrically conductive material, such as copper. The ground layer 30 is disposed on a surface of the main body 10, and electrically connects with the grounding circuits by the via holes 121. In the exemplary embodiment, the ground layer 30 is disposed on the surface of the main body 10 that the first and second connectors 112, 132 are disposed. The ground layer 30 includes a pasting portion 31, a first elongation 32 and a second elongation 33. The pasting portion 31 is rectangular and pasted on the surface of the main body 10 that the first and second connectors 112, 132 are disposed. The first and second connectors 112, 132 penetrate through the pasting portion 31 and exposed through the pasting portion 31. The first elongation 32 and the second elongation 33 extend outwardly from the two ends of the pasting portion 31, near the first connector 112 and the second connector 132, respectively to provide an enlarged grounding contact area.

It is to be understood that, the ground layer 30 could be a plurality of grounding points or flexible grounding bands disposed on a surface of the main body 10.

It is also to be understood that, the lengths of the first elongation 32 and the second elongation 33 can be varied according to practical needs. The shapes of the first elongation 32 and the second elongation 33 are also not limited to the shapes shown in the drawing and can be changed according to practical needs.

A method for manufacturing the flexible printed circuit 100 may include the following steps.

Providing a conventional flexible printed circuit (namely the main body 10) including a first connecting end 11, a band portion 12 and a second connecting end 13. The first connecting end 11 and the second connecting end 13 have a first connector 112 and a second connector 132, respectively. The first connector 112 and the second connector 132 electrically connect with the first connecting end 11 and the second connecting end 13, respectively.

Defining a plurality of via holes 121 through the band portion 12 of the conventional flexible printed circuit.

Disposing a ground layer 30 on at least one surface of the main body 10 to electrically connect with the grounding circuits of the band portion 12 by the via holes 121.

It is to be understood that the ground layer 30 could be a copper layer attached on the surface of the band portion 12.

The flexible printed circuit 100 provides an enlarged grounding contact area by disposing a ground layer 30 on at least one surface of the main body 10 that efficiently release and manage the electrostatic discharge generated within the electronic device. The flexible printed circuit 100 efficiently avoids the electrostatic discharge disturbing and harming the electronic components and circuit so as to assure the normal run of the electronic device.

Finally, it is to be understood, however, that even though numerous characteristics and advantages of the present invention have been set forth in the foregoing description, together with details of the structure and function of the present invention, the disclosure is illustrative only, and changes may be made in detail, especially in matters of shape, size, and arrangement of parts within the principles of present invention to the full extent indicated by the broad general meaning of the terms in which the appended claims are expressed.

What is claimed is:

1. A flexible printed circuit comprising:
a main body comprising:
a first connecting end having a first connector disposed thereon;
a second connecting end having a second connector disposed thereon; and
a band portion having a plurality of circuits disposed therein and a plurality of via holes, the circuits electrically connecting the first connector to the second connector, and including grounding circuits; and
at least one grounding layer disposed on at least one surface of the main body, and electrically connected with the grounding circuits by the via holes.

2. The flexible printed circuit as claimed in claim 1, wherein the ground layer includes a pasting portion pasted on one surface of the main body and at least one elongation extending outwardly from a side of the pasting portion.

3. The flexible printed circuit as claimed in claim 2, wherein the pasting portion is rectangular and pasted on the surface of the main body with the first connector and the second connector disposed thereon; the first connector and the second connector penetrating and emerging through the pasting portion.

4. The flexible printed circuit as claimed in claim 2, wherein the elongation includes a first elongation and a second elongation, the elongations extending outwardly from the two ends of the pasting portion that near the first connector and the second connector, respectively, to enlarge the grounding contact area of the ground layer.

5. The flexible printed circuit as claimed in claim 1, wherein the ground layer is a plurality of grounding points or flexible grounding bands disposed on one surface of the main body.

6. The flexible printed circuit as claimed in claim 1, wherein the ground layer is made of electrically conductive material.

7. The flexible printed circuit as claimed in claim 6, wherein the electrically conductive material is copper.

8. A method for making the flexible printed circuit including the following steps:
providing a flexible printed circuit including a first connecting end, a band portion and a second connecting end, the first connecting end and the second connecting end having a first connector and a second connector disposed thereon respectively and electrically connecting the first connector and a second connector with the first connecting end and the second connecting end, respectively;
defining a plurality of via holes through the band portion of the flexible printed circuit; and
disposing a ground layer on at least one surface of the main body to electrically connect with the grounding circuits by the via holes.

9. The method for making the flexible printed circuit as claimed in claim 8, wherein the step of disposing a ground layer includes pasting a copper layer on the surface of the band portion.

10. The method for making the flexible printed circuit as claimed in claim 8, wherein the step of disposing a ground layer includes pasting a pasting portion on one surface of the main body and providing at least one elongation extending outwardly from one side of the pasting portion.

11. The method for making the flexible printed circuit as claimed in claim 8, further comprising providing the first connecting end with a first connector disposed thereon and electrically connected with the first connecting end and providing the second connecting end with a second connector disposed thereon and electrically connected with the second connecting end.
